(19) United States
(12) Patent Application Publication
(10) Pub. No.: US 2026/0182403 A1
(43) Pub. Date: Jun. 25, 2026

(54) TECHNOLOGIES FOR NANOWIRES IN THROUGH-GLASS VIAS

(71) Applicant: Intel Corporation, Santa Clara, CA (US)

(72) Inventors: Shayan Kaviani, Phoenix, AZ (US); Marcel A. Wall, Phoenix, AZ (US); Ehsan Zamani, Phoenix, AZ (US); Elham Tavakoli, Phoenix, AZ (US); Mahdi Mohammadighaleni, Phoenix, AZ (US); Darko Grujicic, Chandler, AZ (US); Rengarajan Shanmugam, Tempe, AZ (US); Roozbeh Danaei, Phoenix, AZ (US); Srinivas Venkata Ramanuja Pietambaram, Chandler, AZ (US)

(73) Assignee: Intel Corporation, Santa Clara, CA (US)

(21) Appl. No.: 18/988,313

(22) Filed: Dec. 19, 2024

(51) Int. Cl. H01L 23/498; H01L 21/768; H01L 23/08; H10D 30/00; H10D 30/01; H10D 30/43; H10D 30/67

(52) U.S. Cl. CPC H10W 70/635; H10D 30/014; H10D 30/019; H10D 30/43; H10D 30/501; H10D 30/6735; H10W 20/043; H10W 70/66; H10W 76/18

(57) ABSTRACT

Technologies for nanowires in through-glass vias are disclosed. In an illustrative embodiment, zinc oxide nanowires are formed in cavities formed in a glass core. Particles of palladium are deposited on the zinc oxide nanowires. The palladium particles act as activators, allowing for the deposition of a copper seed layer, which can be electroplated to form vias in the cavities. The zinc oxide nanowires and palladium particles can be uniformly deposited on the side walls of the cavities of the glass core, allowing for a uniform copper seed layer. In some embodiments, the nanowires can act as a buffer between the copper vias and the glass core, accommodating thermal expansion of the copper vias and reducing stress on the glass core.

### BACKGROUND

Glass cores for circuit boards and other electronic components are becoming more common. In order to transport power and data signals through the glass cores, through-glass vias (TGVs) can be formed in the glass cores. The vias may be made of copper or other conductive material. However, the coefficient of thermal expansion (CTE) of the glass core and the vias may be mismatched, causing stress when subject to thermal cycling. In some cases, the stress can cause cracks in the glass cores.

### BRIEF DESCRIPTION OF THE DRAWINGS

FIG. 1 is an isometric view of one embodiment of a system with an integrated circuit component on a circuit board with a substrate core.

FIG. 2 is a cross-sectional view of one embodiment of the system of FIG. 1.

FIG. 3 is a flowchart of one embodiment of a method of creating one embodiment of the system of FIG. 1.

FIG. 4 is a cross-sectional view of one embodiment of a glass core at one stage of the flowchart of FIG. 3.

FIG. 5 is a cross-sectional view of one embodiment of a glass core at one stage of the flowchart of FIG. 3.

FIG. 6 is a cross-sectional view of one embodiment of a glass core at one stage of the flowchart of FIG. 3.

FIG. 7 is a cross-sectional view of one embodiment of a glass core at one stage of the flowchart of FIG. 3.

FIG. 8 is a cross-sectional view of one embodiment of a glass core at one stage of the flowchart of FIG. 3.

FIG. 9 is a top view of a wafer and dies that may be included in a microelectronic assembly, in accordance with any of the embodiments disclosed herein.

FIG. 10 is a cross-sectional side view of an integrated circuit device that may be included in a microelectronic assembly, in accordance with any of the embodiments disclosed herein.

FIGS. 11A-11D are perspective views of example planar, gate-all-around, and stacked gate-all-around transistors.

FIG. 12 is a cross-sectional side view of an integrated circuit device assembly that may include a microelectronic assembly, in accordance with any of the embodiments disclosed herein.

FIG. 13 is a block diagram of an example electrical device that may include a microelectronic assembly, in accordance with any of the embodiments disclosed herein.

### DETAILED DESCRIPTION

In various embodiments disclosed herein, an integrated circuit component has a circuit board with a semiconductor die disposed on its surface. The circuit board has a substrate core with through-glass vias (TGVs) defined in cavities extending through the substrate core. In an illustrative embodiment, zinc oxide nanowires extend from side walls of the cavity, and the vias are supported by the nanowires. The nanowires can both allow for easier plating of high-aspect-ratio through-glass vias as well as act as a buffer between the vias and the glass core, accommodating thermal expansion of the vias and other conductive components located on the glass core.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

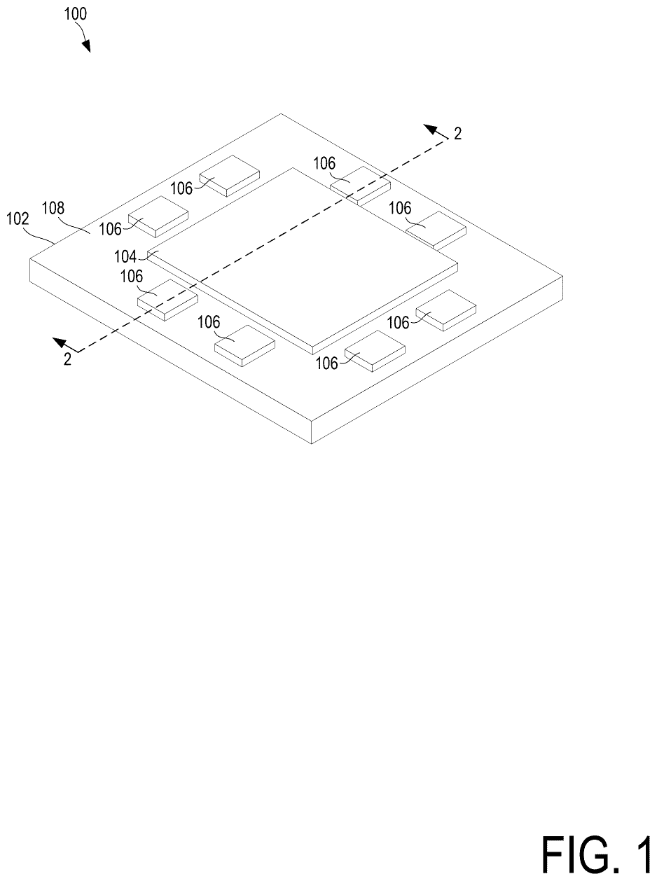

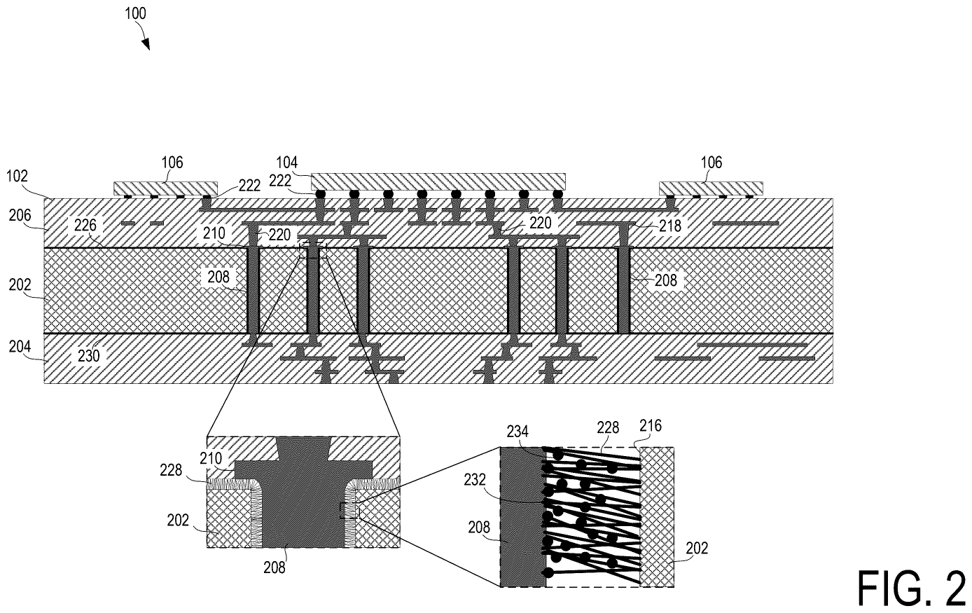

Referring now to FIGS. 1 and 2, in one embodiment, an integrated circuit component 100 includes a circuit board 102 on which one or more dies 104 are mounted. FIG. 1 shows an isometric view of the integrated circuit component 100, and FIG. 2 shows a cross-sectional view of the integrated circuit component 100. As shown in FIG. 1, a die 104 such as a processor die 104 may be disposed on the top surface 108 of the circuit board 102. In an illustrative embodiment, additional components, such as other semiconductor dies 106 (such as memory dies, other processor dies, etc.), are disposed on the top surface 108 of the circuit board 102 as well.

It should be appreciated that, as used herein, the “top side,” “bottom side,” etc., is an arbitrary designation used for clarity and does not denote a particular required orientation for manufacture or use. Although the illustrative embodiment described has the dies 104, 106 placed on the “top” side of the circuit board 102, in some embodiments, those components may be placed on the “bottom” side of the circuit board 102.

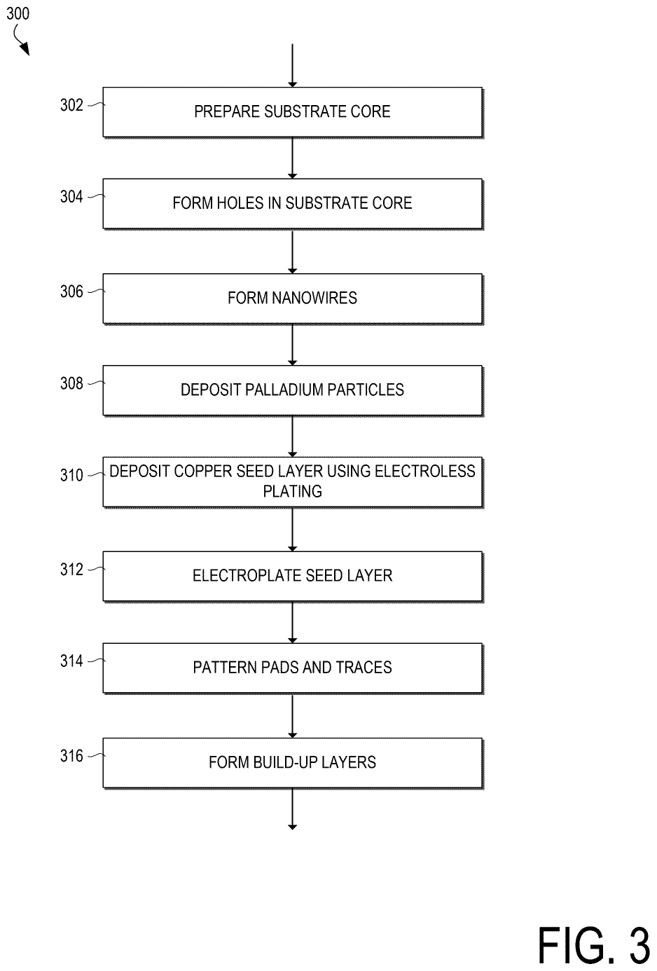

The circuit board 102 includes a substrate core 202, lower build-up layers 204, and upper build-up layers 206. Holes or cavities are defined in the substrate core 202 that extend from the top side 226 of the substrate core 202 to the bottom side 230 of the substrate core 202. Vias 208 are disposed in the holes. In an illustrative embodiment, zinc oxide nanowires 228 extend from the side walls of the cavities defined in the substrate core 202, as well as from the top side 226 and the bottom side 230 of the substrate core 202. In some embodiments, the nanowires 228 may extend from the side walls 216 but not from the top side 226 and/or the bottom side 230. Particles 234 of palladium may be embedded in the nanowires 228. Additionally or alternatively, in some embodiments, the particles 234 may include other materials, such as silver, gold, nickel, cobalt, etc. As discussed in more detail below in regard to FIG. 3, the nanowires 228 and particles 234 of palladium can facilitate growth of a seed layer of copper or other metal in the vias 208 through electroless plating. The nanowires 228 may also act as a buffer between the vias 208, pads 210, and other traces located on the substrate core 202 and the substrate core 202 itself, reducing stress. For example, due to different coefficients of thermal expansion, the vias 208 may expand more than the substrate core 202 in response to a temperature change. Without the nanowires 228, the change in thermal expansion may result in stress between the vias 208 and the substrate core 202, potentially damaging a component. The nanowires 228 have space between them, allowing the nanowires 228 to flex and move, accommodating thermal expansion of the vias 208. The spaces between the nanowires 228 may be empty or filled with any suitable material, such as air, nitrogen, oxygen, argon, a liquid buffer, a solid buffer, etc.

As a result of the nanowires 228, there may be a gap between the vias 208 and the side walls 216 of the cavities. The gap may be, e.g., 10-5,000 nanometers, with an average gap of, e.g., 50-5,000 nanometers. As discussed in more detail below, the vias 208 are plated on the nanowires 228 and are seeded on the particles 234 of palladium. As a result, in an illustrative embodiment, the vias 208 do not extend significantly below the distal ends 232 of the nanowires 228. In other embodiments, depending on factors such as, e.g., the density of particles 234 of palladium, the density of the nanowires 228, etc., the vias 208 may extend close to or be partially or fully in contact with the side walls 216, top side 226, and/or bottom side 230 of the substrate core 202.

In an illustrative embodiment, most of the surface area of the via 208 is not in contact with the side walls 216. For example, a cross-section taken perpendicular to a via 208 may show that the via 208 is not touching the side walls 216 at all at that cross-section. In general, less than half (e.g., 50%-1% or even less) of the surface area of the via 208 will be in contact with the side walls 216. Because the vias 208 are not anchored to the side walls 216, when the integrated circuit component 100 is thermally cycled, the vias 208 can expand and contract due to elastic deformation independently of the substrate core 202, which can mitigate cracking in the substrate core 202.

In an illustrative embodiment, the circuit board 102 is a multi-layer circuit board 102 with build-up layers 204, 206 above and below the substrate core 202. The build-up layers 204, 206 may have any suitable number of layers, such as 1-10 layers each. In other embodiments, the circuit board 102 may be a single-layer circuit board 102.

In an illustrative embodiment, the substrate core 202 is an inorganic core, such as a glass core. The glass core may be silicon oxide glass. In other embodiments, the glass core may be made of any suitable material that may be crystalline, non-crystalline, amorphous, etc., such as fused silicon, borosilicate, sapphire, yttrium aluminum garnet, etc. The glass core may be, e.g., aluminosilicate glass, borosilicate glass, alumino-borosilicate glass, silica, fused silica. The glass core may include one or more additives, such as Al2O3, B2O3, MgO, CaO, SrO, BaO, SnO2, Na2O, K2O, SrO, P2O3, ZrO2, Li2O, Ti, and Zn. The glass core may comprise silicon and oxygen, as well as any one or more of aluminum, boron, magnesium, calcium, barium, tin, sodium, potassium, strontium, phosphorus, zirconium, lithium, titanium, and zinc. The glass core may include at least 20-40 percent silicon by weight, at least 20-40 percent oxygen by weight, and at least 5 percent aluminum by weight. For example, some embodiments of the glass core may include, e.g., at least 20-23 percent silicon and at least 20-26 percent oxygen by weight. In other embodiments, the substrate core 202 may be an organic core, such as a fiberglass board made of glass fibers and a resin, such as FR-4.

In embodiments with a glass core, the vias 208 may be referred to as through-glass vias. In embodiments with a different core, such as an organic core, the vias 208 may be referred to as through-substrate vias.

The thickness of the circuit board 102 may be any suitable thickness, such as 100 micrometers to 5 millimeters. The thickness of the substrate core 202 may be any suitable thickness, such as 50 micrometers to 2 millimeters. The circuit board 102 can have any suitable length and width, such as 1-500 millimeters. Although shown as a rectangle, it should be appreciated that the circuit board 102 may be any suitable shape and may have protrusions, cutouts, etc., in order to accommodate, fit, or touch other components of a device. In the illustrative embodiment, the circuit board 102 is planar. In other embodiments, the circuit board 102 may be non-planar.

In an illustrative embodiment, the die 104 is a processor die, and other dies 106 may be memory dies communicatively coupled to the processor die 104. In other embodiments, the die 104 and/or the dies 106 may be any suitable die, such as one or more processor dies, memory dies, central processing units (CPUs), graphics processing units (CPUs), any other suitable processing units (xPUs), accelerator circuits, a field-programmable gate arrays (FPGA), application-specific integrated circuits (ASICs), etc. The dies 104, 106 may be connected to contact pads or vias 220 on the circuit board 102 through conductive contacts 222, such as solder balls.

The vias 208 in the core 202 may transport power and/or data signals through the substrate core 202. In an illustrative embodiment, the vias 208 are made of copper. In other embodiments, the vias 208 may be made of any suitable conductive material, such as tungsten, polysilicon, etc. The core 202 may have any suitable number of vias 208 extending through it, such as 1-10,000 vias 208. The vias 208 may have any suitable diameter, such as 10-500 micrometers. The vias 208 may be connected to other traces 218, vias 220, etc., on the build-up layers 204, 206 to connect to various components on the top surface or bottom surface of the circuit board 102. The traces 218 and vias 220 may be made of any suitable conductive material, such as copper or aluminum.

In an illustrative embodiment, the vias 208 are high-aspect-ratio vias, such as vias with an aspect ratio of 5-100 or higher. In other embodiments, the vias 208 may have a lower aspect ratio, such as an aspect ratio of 5 or less.

The build-up layers 204, 206 may be made of any suitable material or materials, such as any suitable dielectric that can support the traces 218, vias 220, etc. In an illustrative embodiment, the build-up layers 204, 206 may be made of a resin material filled with a filler, such as Ajinomoto build-up film (ABF).

In an illustrative embodiment, the nanowires 228 are zinc oxide nanowires. In other embodiments, other types of nanowires may be used. The nanowires 228 may have any suitable diameter, such as 100-1,500 nanometers. The nanowires 228 may have any suitable length, such as 100 nanometers or less or up to 5 micrometers or longer. The nanowires 228 may have any suitable density, such as from 10⁴ nanowires per cm² up to 10¹⁰ nanowires per cm², and the nanowires 228 may have any suitable fill factor, such as much less than 1% up to 50%. Of course, a fill factor of at least, e.g., 1%-10% may be preferred in order to provide locations for the vias 208 to be grown, in order to provide support for the vias 208, and/or to prevent the vias 208 from contacting the side walls 216 or other surfaces of the substrate core 202.

As discussed in more detail below, the particles 234 may improve the process of depositing a seed layer using electroless plating. In an illustrative embodiment, the particles 234 are nanoparticles or nanocrystals of palladium. The particles 234 may be, e.g., 50%-100% palladium by weight. The particles 234 may have any suitable diameter, such as 10-500 nanometers. The particles 234 may be roughly spherical or may have a different shape. The particles 234 may have any suitable density within the array of nanowires 228, such as 10³ to 10¹⁰ particles 234 per cm².

Referring now to FIG. 3, in one embodiment, a flowchart for a method 300 for creating the integrated circuit component 100 is shown. The method 300 may be executed by a technician and/or by one or more automated machines. In some embodiments, one or more machines may be programmed to do some or all of the steps of the method 300. Such a machine may include, e.g., a memory, a processor, data storage, etc. The memory and/or data storage may store instructions that, when executed by the machine, cause the machine to perform some or all of the steps of the method 300. The method 300 may use any suitable set of techniques that are used in semiconductor processing or circuit board processing, such as chemical vapor deposition, chemical bath deposition, wet processes, dry processes, atomic layer deposition, physical layer deposition, molecular beam epitaxy, layer transfer, photolithography, ion implantation, dry etching, wet etching, selective laser etching, thermal treatments, flip chip, layer transfer, magnetron sputter deposition, pulsed laser deposition, laser machining, laser-induced deep etching, 3D photolithography, screen printing, ink jet printing, etc. It should be appreciated that the method 300 is merely one embodiment of a method to create one embodiment of a system, and other methods may be used to create any suitable embodiment of the system. In some embodiments, steps of the method 300 may be performed in a different order than that shown in the flowchart.

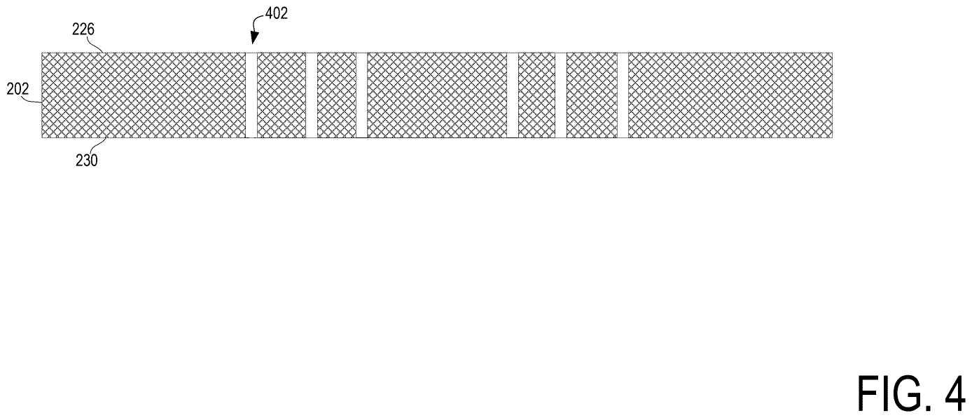

The method 300 begins in block 302, in which a substrate core 202 is prepared, such as by dicing, polishing, etc. In block 304, cavities 402 or holes are formed in the substrate core, as shown in FIG. 4. In an illustrative embodiment, laser-induced deep etching (LIDE) is used to form the cavities 402. In other embodiments, other techniques may be used, such as laser drilling, mechanical drilling, etching, etc. In some embodiments, such as ones in which LIDE is used to form the cavities 402, the cavities 402 may have a different shape, such as an hourglass shape, rather than a cylindrical shape.

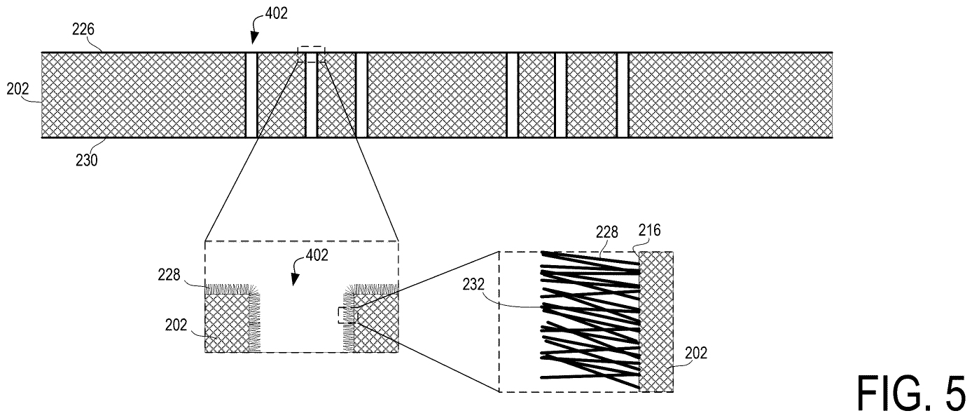

In block 306, nanowires 228 may be formed on some or all of the surfaces of the substrate core 202, such as the side walls 216, the top side 226, and/or the bottom side 230 of the substrate core 202, as shown in FIG. 5.

The nanowires 228 may be formed in any suitable manner. For example, in an illustrative embodiment, a chemical bath deposition (CBD) may be used. Zinc oxide may be dissolved in a solvent, and the substrate core 202 may be immersed in the solution. A seed layer of zinc oxide nuclei will be deposited on some or all of the surfaces of the substrate core 202. The substrate core 202 is then placed in another solution that has zinc salts in it with some additives in an organic solvent. The nuclei formed in the first step allow for growth of the zinc oxide nanowires. The density and diameter of the nanowires 228 can be controlled based on the density and size of nuclei formed in the first step, and the length of the nanowires 228 can be controlled by controlling the growth conditions (such as temperature, time, etc.) of the nanowires 228 in the second step.

In an illustrative embodiment, the nanowires 228 are allowed to remain on the top side 226 and bottom side 230 of the substrate core 202 as well as on the side walls 216 of the cavities 402. In some embodiments, the nanowires 228 may be removed from, e.g., the top side 226 and/or the bottom side 230, such as by mechanical polishing.

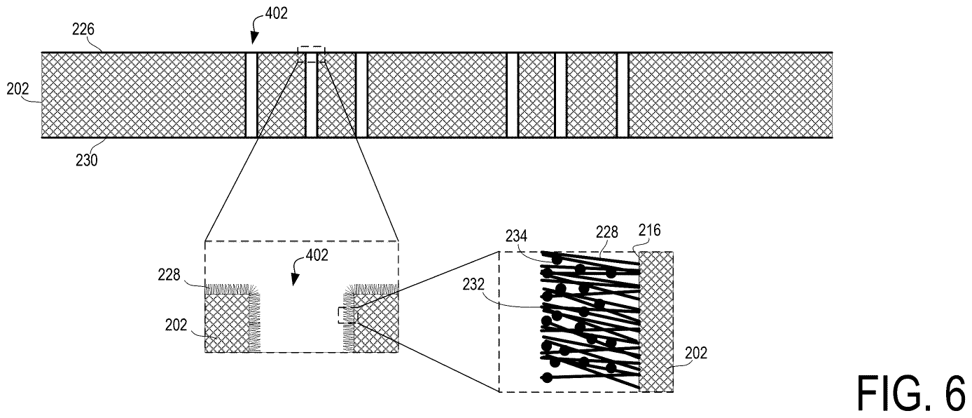

In block 308, particles 234 of palladium are deposited on the nanowires 228, as shown in FIG. 6. The particles 234 may be deposited in any suitable manner. For example, in one embodiment, stannous chloride in a solution is applied to the nanowires 228, forming tin deposits, and then palladium chloride in a solution is applied, and the tin ions reduce the palladium ions to palladium metal. In other embodiments, other approaches may be used.

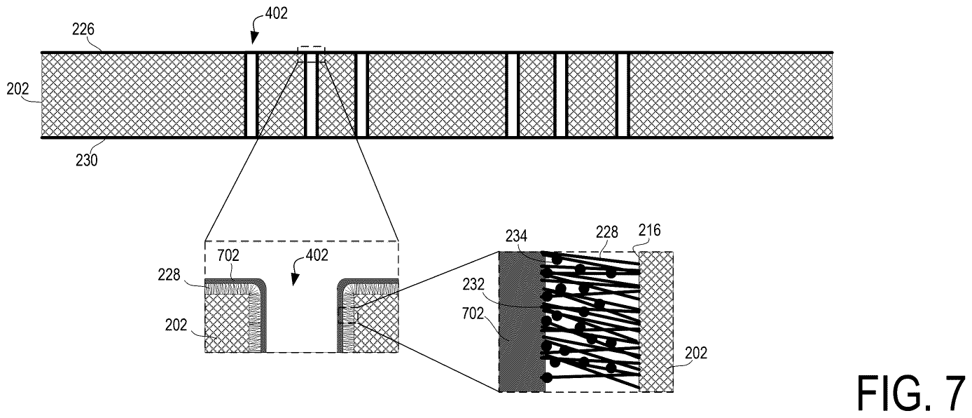

In block 310, a seed layer 702, such as a copper seed layer, may be formed at the distal ends 232 of the nanowires 228, as shown in FIG. 7. In an illustrative embodiment, the copper seed layer 702 is formed using electroless plating. The particles 234 of palladium may act as activators or catalysts for depositing the seed layer 702. The seed layer 702 may have any suitable thickness, such as 0.1-5 micrometers.

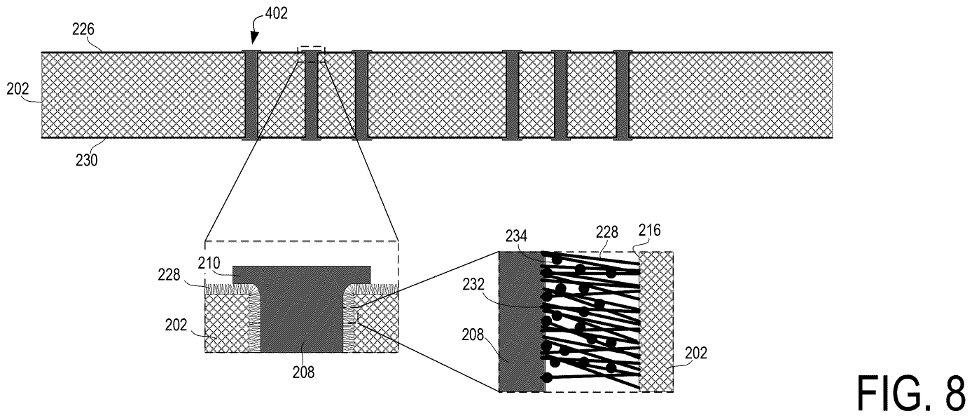

In block 312, the seed layer 702 is electroplated, forming vias 208 in the cavities 402. In block 314, pads 210 and traces may be formed using some or all of the electroplated seed layer. The seed layer 702 may then be removed, as shown in FIG. 8.

It should be appreciated that, in the illustrative embodiment, a fragment of the seed layer 702 remains under the pad 210 and on the outer edges of the vias 208 closest to the side walls 216. It should be appreciated that, in a microscopic view such as using a TEM or SEM, there may be an observable interface between the seed layer 702 and the rest of the vias 208 and/or pads 210. For example, the grain structure may be different in the seed layer 702 than in the rest of the vias 208 and/or pads 210.

After the via 208 is formed and the seed layer 702 is removed, additional processing may proceed in block 316. For example, the build-up layers 204, 206 may be built up on the substrate core 202, one or more dies 104, 106 are mounted on the substrate, etc., completing the integrated circuit component 100, as shown in FIG. 2.

It should be appreciated that various embodiments of the approach described above can provide several advantages. For example, without using the nanowires 228, it may be difficult to uniformly deposit particles 234 of palladium in cavities 402 with a high aspect ratio, due to a high viscosity of the palladium solution. However, the solutions used to grow the nanowires 228 may have a lower viscosity, allowing them to more easily penetrate into the cavities 402. The palladium can then be more easily applied due to the presence of the nanowires 228. In some embodiments, the cavities may not have a high aspect ratio.

It should be appreciated that the deposition of the nanowires 228, particles 234, and seed layer 702 can all be done through wet processes, which may be less expensive and more scalable than alternatives, allowing for high throughput operation.

It should further be appreciated that the nanowires 228 do not form a full, solid layer. Rather, there are gaps between the nanowires 228. The gaps can accommodate expansion of the vias 208, such as due to thermal expansion, without applying a significant stress to the substrate core 202.

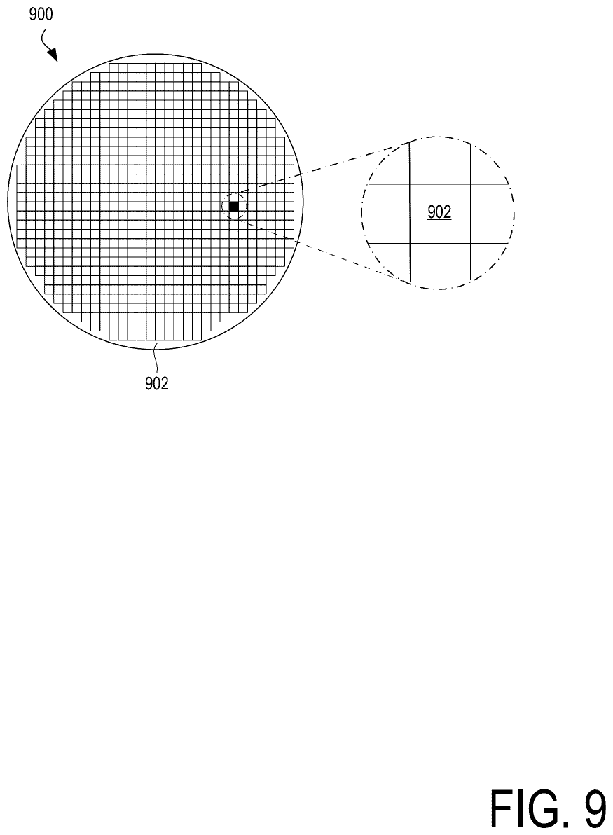

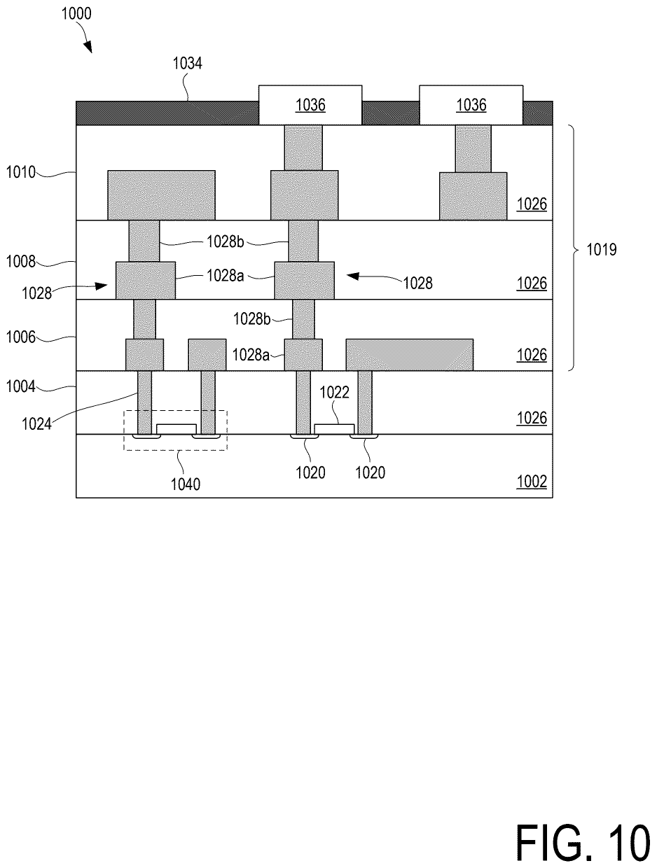

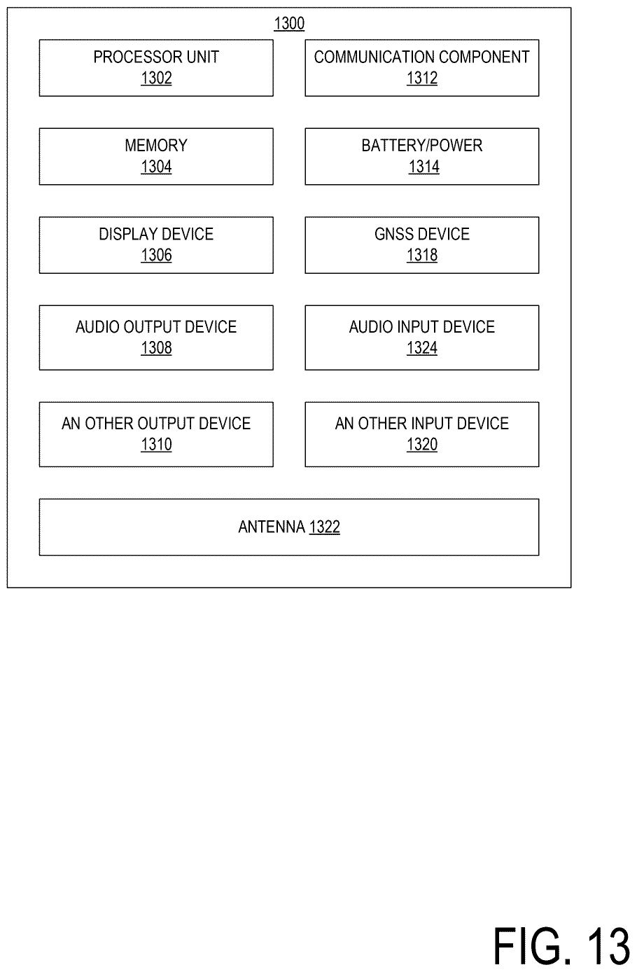

FIG. 9 is a top view of a wafer 900 and dies 902 that may be included in any of the integrated circuit components 100 disclosed herein (e.g., as any suitable ones of the dies 104, 106). The wafer 900 may be composed of semiconductor material and may include one or more dies 902 having integrated circuit structures formed on a surface of the wafer 900. The individual dies 902 may be a repeating unit of an integrated circuit product that includes any suitable integrated circuit. After the fabrication of the semiconductor product is complete, the wafer 900 may undergo a singulation process in which the dies 902 are separated from one another to provide discrete “chips” of the integrated circuit product. The die 902 may be any of the dies 104, 106 disclosed herein. The die 902 may include one or more transistors (e.g., some of the transistors 1040 of FIG. 10, discussed below), supporting circuitry to route electrical signals to the transistors, passive components (e.g., signal traces, resistors, capacitors, or inductors), and/or any other integrated circuit components. In some embodiments, the wafer 900 or the die 902 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 902. For example, a memory array formed by multiple memory devices may be formed on a same die 902 as a processor unit (e.g., the processor unit 1302 of FIG. 13) or other logic that is configured to store information in the memory devices or execute instructions stored in the memory array. Various ones of the integrated circuit components 100 disclosed herein may be manufactured using a die-to-wafer assembly technique in which some dies 104, 106 are attached to a wafer 900 that include others of the dies 104, 106, and the wafer 900 is subsequently singulated.

FIG. 10 is a cross-sectional side view of an integrated circuit device 1000 that may be included in any of the integrated circuit components 100 disclosed herein (e.g., in any of the dies 104, 106). One or more of the integrated circuit devices 1000 may be included in one or more dies 902 (FIG. 9). The integrated circuit device 1000 may be formed on a die substrate 1002 (e.g., the wafer 900 of FIG. 9) and may be included in a die (e.g., the die 902 of FIG. 9). The die substrate 1002 may be a semiconductor substrate composed of semiconductor material systems including, for example, n-type or p-type materials systems (or a combination of both). The die substrate 1002 may include, for example, a crystalline substrate formed using a bulk silicon or a silicon-on-insulator (SOI) substructure. In some embodiments, the die substrate 1002 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1002. Although a few examples of materials from which the die substrate 1002 may be formed are described here, any material that may serve as a foundation for an integrated circuit device 1000 may be used. The die substrate 1002 may be part of a singulated die (e.g., the dies 902 of FIG. 9) or a wafer (e.g., the wafer 900 of FIG. 9).

The integrated circuit device 1000 may include one or more device layers 1004 disposed on the die substrate 1002. The device layer 1004 may include features of one or more transistors 1040 (e.g., metal oxide semiconductor field-effect transistors (MOSFETs)) formed on the die substrate 1002. The transistors 1040 may include, for example, one or more source and/or drain (S/D) regions 1020, a gate 1022 to control current flow between the S/D regions 1020, and one or more S/D contacts 1024 to route electrical signals to/from the S/D regions 1020. The transistors 1040 may include additional features not depicted for the sake of clarity, such as device isolation regions, gate contacts, and the like. The transistors 1040 are not limited to the type and configuration depicted in FIG. 10 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

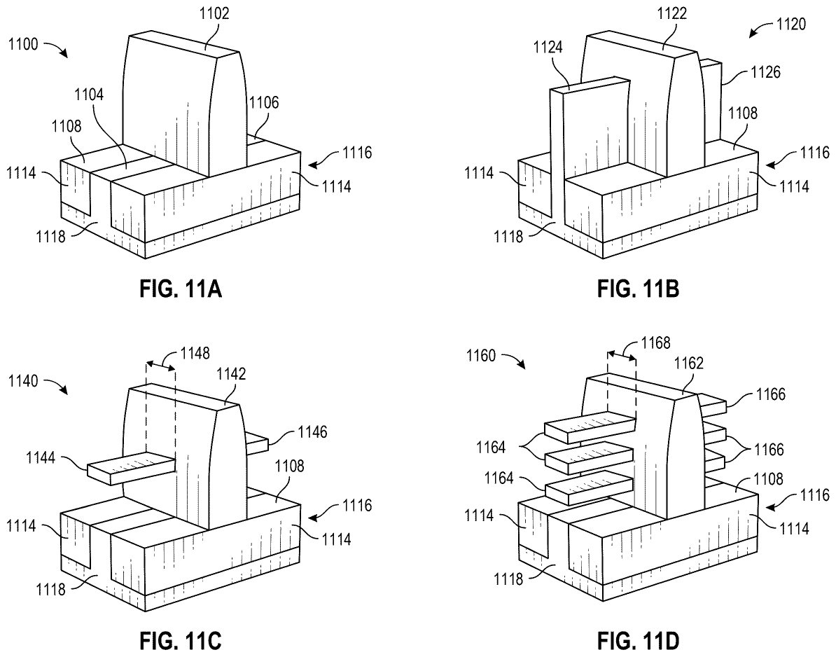

FIGS. 11A-11D are simplified perspective views of example planar, FinFET, gate-all-around, and stacked gate-all-around transistors. The transistors illustrated in FIGS. 11A-11D are formed on a substrate 1116 having a surface 1108. Isolation regions 1114 separate the source and drain regions of the transistors from other transistors and from a bulk region 1118 of the substrate 1116.

FIG. 11A is a perspective view of an example planar transistor 1100 comprising a gate 1102 that controls current flow between a source region 1104 and a drain region 1106. The transistor 1100 is planar in that the source region 1104 and the drain region 1106 are planar with respect to the substrate surface 1108.

FIG. 11B is a perspective view of an example FinFET transistor 1120 comprising a gate 1122 that controls current flow between a source region 1124 and a drain region 1126. The transistor 1120 is non-planar in that the source region 1124 and the drain region 1126 comprise “fins” that extend upwards from the substrate surface 1128. As the gate 1122 encompasses three sides of the semiconductor fin that extends from the source region 1124 to the drain region 1126, the transistor 1120 can be considered a tri-gate transistor. FIG. 11B illustrates one S/D fin extending through the gate 1122, but multiple S/D fins can extend through the gate of a FinFET transistor.

FIG. 11C is a perspective view of a gate-all-around (GAA) transistor 1140 comprising a gate 1142 that controls current flow between a source region 1144 and a drain region 1146. The transistor 1140 is non-planar in that the source region 1144 and the drain region 1146 are elevated from the substrate surface 1128.

FIG. 11D is a perspective view of a GAA transistor 1160 comprising a gate 1162 that controls current flow between multiple elevated source regions 1164 and multiple elevated drain regions 1166. The transistor 1160 is a stacked GAA transistor as the gate controls the flow of current between multiple elevated S/D regions stacked on top of each other. The transistors 1140 and 1160 are considered gate-all-around transistors as the gates encompass all sides of the semiconductor portions that extends from the source regions to the drain regions. The transistors 1140 and 1160 can alternatively be referred to as nanowire, nanosheet, or nanoribbon transistors depending on the width (e.g., widths 1148 and 1168 of transistors 1140 and 1160, respectively) of the semiconductor portions extending through the gate.

Returning to FIG. 10, a transistor 1040 may include a gate 1022 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1040 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1040 along the source-channel-drain direction, the gate electrode may consist of a U-shaped structure that includes a bottom portion substantially parallel to the surface of the die substrate 1002 and two sidewall portions that are substantially perpendicular to the top surface of the die substrate 1002. In other embodiments, at least one of the metal layers that form the gate electrode may simply be a planar layer that is substantially parallel to the top surface of the die substrate 1002 and does not include sidewall portions substantially perpendicular to the top surface of the die substrate 1002. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of individual transistors 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes them to diffuse farther into the die substrate 1002 may follow the ion-implantation process. In the latter process, the die substrate 1002 may first be etched to form recesses at the locations of the S/D regions 1020. An epitaxial deposition process may then be carried out to fill the recesses with material that is used to fabricate the S/D regions 1020. In some implementations, the S/D regions 1020 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1020 may be formed using one or more alternate semiconductor materials such as germanium or a group III-V material or alloy. In further embodiments, one or more layers of metal and/or metal alloys may be used to form the S/D regions 1020.

Electrical signals, such as power and/or input/output (I/O) signals, may be routed to and/or from the devices (e.g., transistors 1040) of the device layer 1004 through one or more interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with the interconnect structures 1028 of the interconnect layers 1006-1010. The one or more interconnect layers 1006-1010 may form a metallization stack (also referred to as an “ILD stack”) 1019 of the integrated circuit device 1000.

The interconnect structures 1028 may be arranged within the interconnect layers 1006-1010 to route electrical signals according to a wide variety of designs; in particular, the arrangement is not limited to the particular configuration of interconnect structures 1028 depicted in FIG. 10. Although a particular number of interconnect layers 1006-1010 is depicted in FIG. 10, embodiments of the present disclosure include integrated circuit devices having more or fewer interconnect layers than depicted.

In some embodiments, the interconnect structures 1028 may include lines 1028a and/or vias 1028b filled with an electrically conductive material such as a metal. The lines 1028a may be arranged to route electrical signals in a direction of a plane that is substantially parallel with a surface of the die substrate 1002 upon which the device layer 1004 is formed. For example, the lines 1028a may route electrical signals in a direction in and out of the page and/or in a direction across the page. The vias 1028b may be arranged to route electrical signals in a direction of a plane that is substantially perpendicular to the surface of the die substrate 1002 upon which the device layer 1004 is formed. In some embodiments, the vias 1028b may electrically couple lines 1028a of different interconnect layers 1006-1010 together.

The interconnect layers 1006-1010 may include a dielectric material 1026 disposed between the interconnect structures 1028, as shown in FIG. 10. In some embodiments, dielectric material 1026 disposed between the interconnect structures 1028 in different ones of the interconnect layers 1006-1010 may have different compositions; in other embodiments, the composition of the dielectric material 1026 between different interconnect layers 1006-1010 may be the same. The device layer 1004 may include a dielectric material 1026 disposed between the transistors 1040 and a bottom layer of the metallization stack as well. The dielectric material 1026 included in the device layer 1004 may have a different composition than the dielectric material 1026 included in the interconnect layers 1006-1010; in other embodiments, the composition of the dielectric material 1026 in the device layer 1004 may be the same as a dielectric material 1026 included in any one of the interconnect layers 1006-1010.

A first interconnect layer 1006 (referred to as Metal 1 or “M1”) may be formed directly on the device layer 1004. In some embodiments, the first interconnect layer 1006 may include lines 1028a and/or vias 1028b, as shown. The lines 1028a of the first interconnect layer 1006 may be coupled with contacts (e.g., the S/D contacts 1024) of the device layer 1004. The vias 1028b of the first interconnect layer 1006 may be coupled with the lines 1028a of a second interconnect layer 1008.

The second interconnect layer 1008 (referred to as Metal 2 or “M2”) may be formed directly on the first interconnect layer 1006. In some embodiments, the second interconnect layer 1008 may include via 1028b to couple the lines 1028 of the second interconnect layer 1008 with the lines 1028a of a third interconnect layer 1010. Although the lines 1028a and the vias 1028b are structurally delineated with a line within individual interconnect layers for the sake of clarity, the lines 1028a and the vias 1028b may be structurally and/or materially contiguous (e.g., simultaneously filled during a dual-damascene process) in some embodiments.

The third interconnect layer 1010 (referred to as Metal 3 or “M3”) (and additional interconnect layers, as desired) may be formed in succession on the second interconnect layer 1008 according to similar techniques and configurations described in connection with the second interconnect layer 1008 or the first interconnect layer 1006. In some embodiments, the interconnect layers that are “higher up” in the metallization stack 1019 in the integrated circuit device 1000 (i.e., farther away from the device layer 1004) may be thicker that the interconnect layers that are lower in the metallization stack 1019, with lines 1028a and vias 1028b in the higher interconnect layers being thicker than those in the lower interconnect layers.

The integrated circuit device 1000 may include a solder resist material 1034 (e.g., polyimide or similar material) and one or more conductive contacts 1036 formed on the interconnect layers 1006-1010. In FIG. 10, the conductive contacts 1036 are illustrated as taking the form of bond pads. The conductive contacts 1036 may be electrically coupled with the interconnect structures 1028 and configured to route the electrical signals of the transistor(s) 1040 to external devices. For example, solder bonds may be formed on the one or more conductive contacts 1036 to mechanically and/or electrically couple an integrated circuit die including the integrated circuit device 1000 with another component (e.g., a printed circuit board). The integrated circuit device 1000 may include additional or alternate structures to route the electrical signals from the interconnect layers 1006-1010; for example, the conductive contacts 1036 may include other analogous features (e.g., posts) that route the electrical signals to external components.

In some embodiments in which the integrated circuit device 1000 is a double-sided die, the integrated circuit device 1000 may include another metallization stack (not shown) on the opposite side of the device layer(s) 1004. This metallization stack may include multiple interconnect layers as discussed above with reference to the interconnect layers 1006-1010, to provide conductive pathways (e.g., including conductive lines and vias) between the device layer(s) 1004 and additional conductive contacts (not shown) on the opposite side of the integrated circuit device 1000 from the conductive contacts 1036.

In other embodiments in which the integrated circuit device 1000 is a double-sided die, the integrated circuit device 1000 may include one or more through silicon vias (TSVs) through the die substrate 1002; these TSVs may make contact with the device layer(s) 1004, and may provide conductive pathways between the device layer(s) 1004 and additional conductive contacts (not shown) on the opposite side of the integrated circuit device 1000 from the conductive contacts 1036. In some embodiments, TSVs extending through the substrate can be used for routing power and ground signals from conductive contacts on the opposite side of the integrated circuit device 1000 from the conductive contacts 1036 to the transistors 1040 and any other components integrated into the die 1000, and the metallization stack 1019 can be used to route I/O signals from the conductive contacts 1036 to transistors 1040 and any other components integrated into the die 1000.

Multiple integrated circuit devices 1000 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

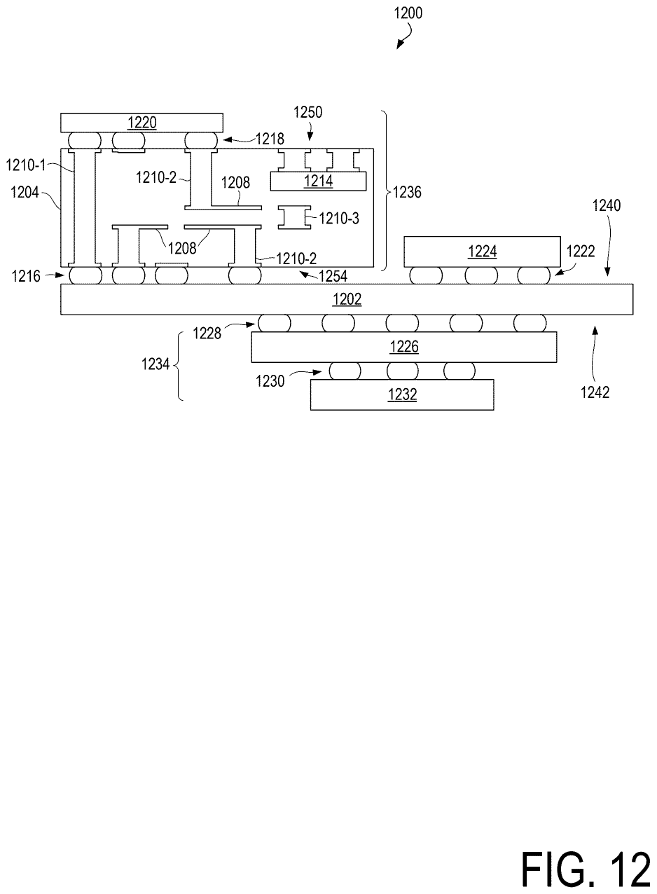

FIG. 12 is a cross-sectional side view of an integrated circuit device assembly 1200 that may include any of the integrated circuit components 100 disclosed herein. In some embodiments, the integrated circuit device assembly 1200 may be a integrated circuit component 100. The integrated circuit device assembly 1200 includes a number of components disposed on a circuit board 1202 (which may be a motherboard, system board, mainboard, etc.). The integrated circuit device assembly 1200 includes components disposed on a first face 1240 of the circuit board 1202 and an opposing second face 1242 of the circuit board 1202; generally, components may be disposed on one or both faces 1240 and 1242. Any of the integrated circuit components discussed below with reference to the integrated circuit device assembly 1200 may take the form of any suitable ones of the embodiments of the integrated circuit components 100 disclosed herein.

In some embodiments, the circuit board 1202 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1202. In other embodiments, the circuit board 1202 may be a non-PCB substrate. In some embodiments the circuit board 1202 may be, for example, the circuit board 102. The integrated circuit device assembly 1200 illustrated in FIG. 12 includes a package-on-interposer structure 1236 coupled to the first face 1240 of the circuit board 1202 by coupling components 1216. The coupling components 1216 may electrically and mechanically couple the package-on-interposer structure 1236 to the circuit board 1202, and may include solder balls (as shown in FIG. 12), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1216 may serve as the coupling components illustrated or described for any of the substrate assembly or substrate assembly components described herein, as appropriate.

The package-on-interposer structure 1236 may include an integrated circuit component 1220 coupled to an interposer 1204 by coupling components 1218. The coupling components 1218 may take any suitable form for the application, such as the forms discussed above with reference to the coupling components 1216. Although a single integrated circuit component 1220 is shown in FIG. 12, multiple integrated circuit components may be coupled to the interposer 1204; indeed, additional interposers may be coupled to the interposer 1204. The interposer 1204 may provide an intervening substrate used to bridge the circuit board 1202 and the integrated circuit component 1220.

The integrated circuit component 1220 may be a packaged or unpacked integrated circuit product that includes one or more integrated circuit dies (e.g., the die 902 of FIG. 9, the integrated circuit device 1000 of FIG. 10) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1220, a single monolithic integrated circuit die comprises solder bumps attached to contacts on the die. The solder bumps allow the die to be directly attached to the interposer 1204. The integrated circuit component 1220 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1220 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1220 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1220 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1204 may spread connections to a wider pitch or reroute a connection to a different connection. For example, the interposer 1204 may couple the integrated circuit component 1220 to a set of ball grid array (BGA) conductive contacts of the coupling components 1216 for coupling to the circuit board 1202. In the embodiment illustrated in FIG. 12, the integrated circuit component 1220 and the circuit board 1202 are attached to opposing sides of the interposer 1204; in other embodiments, the integrated circuit component 1220 and the circuit board 1202 may be attached to a same side of the interposer 1204. In some embodiments, three or more components may be interconnected by way of the interposer 1204.

In some embodiments, the interposer 1204 may be formed as a PCB, including multiple metal layers separated from one another by layers of dielectric material and interconnected by electrically conductive vias. In some embodiments, the interposer 1204 may be formed of an epoxy resin, a fiberglass-reinforced epoxy resin, an epoxy resin with inorganic fillers, a ceramic material, or a polymer material such as polyimide. In some embodiments, the interposer 1204 may be formed of alternate rigid or flexible materials that may include the same materials described above for use in a semiconductor substrate, such as silicon, germanium, and other group III-V and group IV materials. The interposer 1204 may include metal interconnects 1208 and vias 1210, including but not limited to through hole vias 1210-1 (that extend from a first face 1250 of the interposer 1204 to a second face 1254 of the interposer 1204), blind vias 1210-2 (that extend from the first or second faces 1250 or 1254 of the interposer 1204 to an internal metal layer), and buried vias 1210-3 (that connect internal metal layers).

In some embodiments, the interposer 1204 can comprise a silicon interposer. Through silicon vias (TSV) extending through the silicon interposer can connect connections on a first face of a silicon interposer to an opposing second face of the silicon interposer. In some embodiments, an interposer 1204 comprising a silicon interposer can further comprise one or more routing layers to route connections on a first face of the interposer 1204 to an opposing second face of the interposer 1204.

The interposer 1204 may further include embedded devices 1214, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1204. The package-on-interposer structure 1236 may take the form of any of the package-on-interposer structures known in the art.

The integrated circuit device assembly 1200 may include an integrated circuit component 1224 coupled to the first face 1240 of the circuit board 1202 by coupling components 1222. The coupling components 1222 may take the form of any of the embodiments discussed above with reference to the coupling components 1216, and the integrated circuit component 1224 may take the form of any of the embodiments discussed above with reference to the integrated circuit component 1220.

The integrated circuit device assembly 1200 illustrated in FIG. 12 includes a package-on-package structure 1234 coupled to the second face 1242 of the circuit board 1202 by coupling components 1228. The package-on-package structure 1234 may include an integrated circuit component 1226 and an integrated circuit component 1232 coupled together by coupling components 1230 such that the integrated circuit component 1226 is disposed between the circuit board 1202 and the integrated circuit component 1232. The coupling components 1228 and 1230 may take the form of any of the embodiments of the coupling components 1216 discussed above, and the integrated circuit components 1226 and 1232 may take the form of any of the embodiments of the integrated circuit component 1220 discussed above. The package-on-package structure 1234 may be configured in accordance with any of the package-on-package structures known in the art.

FIG. 13 is a block diagram of an example electrical device 1300 that may include one or more of the integrated circuit components 100 disclosed herein. For example, any suitable ones of the components of the electrical device 1300 may include one or more of the integrated circuit device assemblies 1200, integrated circuit components 1220, integrated circuit devices 1000, or integrated circuit dies 902 disclosed herein, and may be arranged in any of the integrated circuit components 100 disclosed herein. A number of components are illustrated in FIG. 13 as included in the electrical device 1300, but any one or more of these components may be omitted or duplicated, as suitable for the application. In some embodiments, some or all of the components included in the electrical device 1300 may be attached to one or more motherboards mainboards, or system boards. In some embodiments, one or more of these components are fabricated onto a single system-on-a-chip (SoC) die.

Additionally, in various embodiments, the electrical device 1300 may not include one or more of the components illustrated in FIG. 13, but the electrical device 1300 may include interface circuitry for coupling to the one or more components. For example, the electrical device 1300 may not include a display device 1306, but may include display device interface circuitry (e.g., a connector and driver circuitry) to which a display device 1306 may be coupled. In another set of examples, the electrical device 1300 may not include an audio input device 1324 or an audio output device 1308, but may include audio input or output device interface circuitry (e.g., connectors and supporting circuitry) to which an audio input device 1324 or audio output device 1308 may be coupled.

The electrical device 1300 may include one or more processor units 1302 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1302 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1300 may include a memory 1304, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1304 may include memory that is located on the same integrated circuit die as the processor unit 1302. This memory may be used as cache memory (e.g., Level 1 (L 1 ), Level 2 (L 2 ), Level 3 (L 3 ), Level 4 (L 4 ), Last Level Cache (LLC)) and may include embedded dynamic random access memory (eDRAM) or spin transfer torque magnetic random access memory (STT-MRAM).

In some embodiments, the electrical device 1300 can comprise one or more processor units 1302 that are heterogeneous or asymmetric to another processor unit 1302 in the electrical device 1300. There can be a variety of differences between the processing units 1302 in a system in terms of a spectrum of metrics of merit including architectural, microarchitectural, thermal, power consumption characteristics, and the like. These differences can effectively manifest themselves as asymmetry and heterogeneity among the processor units 1302 in the electrical device 1300.

In some embodiments, the electrical device 1300 may include a communication component 1312 (e.g., one or more communication components). For example, the communication component 1312 can manage wireless communications for the transfer of data to and from the electrical device 1300. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1312 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP 2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1312 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1312 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1312 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1312 may operate in accordance with other wireless protocols in other embodiments. The electrical device 1300 may include an antenna 1322 to facilitate wireless communications and/or to receive other wireless communications (such as AM or FM radio transmissions).

In some embodiments, the communication component 1312 may manage wired communications, such as electrical, optical, or any other suitable communication protocols (e.g., IEEE 802.3 Ethernet standards). As noted above, the communication component 1312 may include multiple communication components. For instance, a first communication component 1312 may be dedicated to shorter-range wireless communications such as Wi-Fi or Bluetooth, and a second communication component 1312 may be dedicated to longer-range wireless communications such as global positioning system (GPS), EDGE, GPRS, CDMA, WiMAX, LTE, EV-DO, or others. In some embodiments, a first communication component 1312 may be dedicated to wireless communications, and a second communication component 1312 may be dedicated to wired communications.

The electrical device 1300 may include battery/power circuitry 1314. The battery/power circuitry 1314 may include one or more energy storage devices (e.g., batteries or capacitors) and/or circuitry for coupling components of the electrical device 1300 to an energy source separate from the electrical device 1300 (e.g., AC line power).

The electrical device 1300 may include a display device 1306 (or corresponding interface circuitry, as discussed above). The display device 1306 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1300 may include an audio output device 1308 (or corresponding interface circuitry, as discussed above). The audio output device 1308 may include any embedded or wired or wirelessly connected external device that generates an audible indicator, such as speakers, headsets, or earbuds.

The electrical device 1300 may include an audio input device 1324 (or corresponding interface circuitry, as discussed above). The audio input device 1324 may include any embedded or wired or wirelessly connected device that generates a signal representative of a sound, such as microphones, microphone arrays, or digital instruments (e.g., instruments having a musical instrument digital interface (MIDI) output). The electrical device 1300 may include a Global Navigation Satellite System (GNSS) device 1318 (or corresponding interface circuitry, as discussed above), such as a Global Positioning System (GPS) device. The GNSS device 1318 may be in communication with a satellite-based system and may determine a geolocation of the electrical device 1300 based on information received from one or more GNSS satellites, as known in the art.

The electrical device 1300 may include an other output device 1310 (or corresponding interface circuitry, as discussed above). Examples of the other output device 1310 may include an audio codec, a video codec, a printer, a wired or wireless transmitter for providing information to other devices, or an additional storage device.

The electrical device 1300 may include an other input device 1320 (or corresponding interface circuitry, as discussed above). Examples of the other input device 1320 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1300 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1300 may be any other electronic device that processes data. In some embodiments, the electrical device 1300 may comprise multiple discrete physical components. Given the range of devices that the electrical device 1300 can be manifested as in various embodiments, in some embodiments, the electrical device 1300 can be referred to as a computing device or a computing system.

### EXAMPLES

Illustrative examples of the technologies disclosed herein are provided below. An embodiment of the technologies may include any one or more, and any combination of, the examples described below.

Example 1 includes an apparatus comprising a substrate core, the substrate core comprising a top side and a bottom side, wherein a plurality of cavities are defined within the substrate core, wherein individual cavities of the plurality of cavities extend from the bottom side to the top side, wherein individual cavities of the plurality of cavities have one or more side walls; a plurality of vias extending through the plurality of cavities defined in the substrate core; and a plurality of nanowires extending from the one or more side walls of the plurality of cavities.

Example 2 includes the subject matter of Example 1, and wherein individual nanowires of the plurality of nanowires have a length of 100-5,000 nanometers and a diameter of 50-1,000 nanometers.

Example 3 includes the subject matter of any of Examples 1 and 2, and wherein individual nanowires of the plurality of nanowires have a ratio of length to diameter of at least 3.

Example 4 includes the subject matter of any of Examples 1-3, and wherein individual nanowires of the plurality of nanowires comprise zinc and oxygen.

Example 5 includes the subject matter of any of Examples 1-4, and wherein the plurality of nanowires extend from the one or more side walls of the plurality of cavities to a via of the plurality of vias.

Example 6 includes the subject matter of any of Examples 1-5, and wherein the plurality of vias are not in contact with the one or more side walls of the plurality of cavities.

Example 7 includes the subject matter of any of Examples 1-6, and further including a plurality of particles embedded within the plurality of nanowires, wherein individual particles of the plurality of particles comprise palladium.

Example 8 includes the subject matter of any of Examples 1-7, and wherein the plurality of nanowires are able to accommodate thermal expansion of the plurality of vias.

Example 9 includes the subject matter of any of Examples 1-8, and wherein individual cavities of the plurality of cavities have an aspect ratio of at least 10.

Example 10 includes the subject matter of any of Examples 1-9, and further including a second plurality of nanowires extending from the top side of the substrate core; and a third plurality of nanowires extending from the bottom side of the substrate core.

Example 11 includes the subject matter of any of Examples 1-10, and wherein individual vias of the plurality of vias are not anchored to side walls of a corresponding cavity of the plurality of cavities.

Example 12 includes the subject matter of any of Examples 1-11, and wherein a gap of at least 10 nanometers is present between at least part of individual vias of the plurality of vias and side walls of a corresponding cavity of the plurality of cavities.

Example 13 includes the subject matter of any of Examples 1-12, and wherein cross-sections of individual vias of the plurality of vias taken perpendicular to the individual vias do not contact the one or more side walls of a corresponding cavity of the plurality of cavities.

Example 14 includes the subject matter of any of Examples 1-13, and wherein the substrate core is a glass core.

Example 15 includes the subject matter of any of Examples 1-14, and further including a plurality of build-up layers adjacent the top side and the bottom side; and one or more semiconductor dies mounted on a build-up layer of the plurality of build-up layers.

Example 16 includes an apparatus comprising a substrate core, the substrate core comprising a top side and a bottom side, wherein a plurality of cavities are defined within the substrate core, wherein individual cavities of the plurality of cavities extend from the bottom side to the top side, wherein individual cavities of the plurality of cavities have one or more side walls; and a plurality of nanowires extending from the one or more side walls of the plurality of cavities, wherein individual nanowires of the plurality of nanowires comprise zinc and oxygen.

Example 17 includes the subject matter of Example 16, and wherein individual nanowires of the plurality of nanowires have a length of 100-5,000 nanometers and a diameter of 50-1,000 nanometers.

Example 18 includes the subject matter of any of Examples 16 and 17, and wherein individual nanowires of the plurality of nanowires have a ratio of length to diameter of at least 3.

Example 19 includes the subject matter of any of Examples 16-18, and further including a plurality of particles embedded within the plurality of nanowires, wherein individual particles of the plurality of particles comprise palladium.

Example 20 includes the subject matter of any of Examples 16-19, and wherein individual cavities of the plurality of cavities have an aspect ratio of at least 10.

Example 21 includes the subject matter of any of Examples 16-20, and further including a second plurality of nanowires extending from the top side of the substrate core; and a third plurality of nanowires extending from the bottom side of the substrate core.

Example 22 includes the subject matter of any of Examples 16-21, and further including a plurality of build-up layers adjacent the top side and the bottom side; and one or more semiconductor dies mounted on a build-up layer of the plurality of build-up layers.

Example 23 includes the subject matter of any of Examples 16-22, and further including a plurality of vias extending through the plurality of cavities defined in the substrate core.

Example 24 includes the subject matter of any of Examples 16-23, and wherein the plurality of nanowires extend from the one or more side walls of the plurality of cavities to a via of the plurality of vias.

Example 25 includes the subject matter of any of Examples 16-24, and wherein the plurality of vias are not in contact with the one or more side walls of the plurality of cavities.

Example 26 includes the subject matter of any of Examples 16-25, and wherein the plurality of nanowires are able to accommodate thermal expansion of the plurality of vias.

Example 27 includes the subject matter of any of Examples 16-26, and wherein individual vias of the plurality of vias are not anchored to side walls of a corresponding cavity of the plurality of cavities.

Example 28 includes the subject matter of any of Examples 16-27, and wherein a gap of at least 10 nanometers is present between at least part of individual vias of the plurality of vias and side walls of a corresponding cavity of the plurality of cavities.

Example 29 includes the subject matter of any of Examples 16-28, and wherein cross-sections of individual vias of the plurality of vias taken perpendicular to the individual vias do not contact the one or more side walls of a corresponding cavity of the plurality of cavities.

Example 30 includes the subject matter of any of Examples 16-29, and wherein the substrate core is a glass core.

Example 31 includes a method comprising creating a plurality of cavities in a glass core; forming a plurality of nanowires in the plurality of cavities; and electrolessly plating a seed layer in the plurality of cavities.

Example 32 includes the subject matter of Example 31, and further including attaching a plurality of particles to the plurality of nanowires before electrolessly plating the seed layer, wherein individual particles of the plurality of particles comprise palladium.

Example 33 includes the subject matter of any of Examples 31 and 32, and wherein individual nanowires of the plurality of nanowires have a length of 100-5,000 nanometers and a diameter of 50-1,000 nanometers.

Example 34 includes the subject matter of any of Examples 31-33, and wherein individual nanowires of the plurality of nanowires have a ratio of length to diameter of at least 3.

Example 35 includes the subject matter of any of Examples 31-34, and wherein individual nanowires of the plurality of nanowires comprise zinc and oxygen.

Example 36 includes the subject matter of any of Examples 31-35, and wherein individual cavities of the plurality of cavities have an aspect ratio of at least 10.

Example 37 includes the subject matter of any of Examples 31-36, and further including forming a second plurality of nanowires extending from a top side of the glass core; and forming a third plurality of nanowires extending from a bottom side of the glass core.

Example 38 includes the subject matter of any of Examples 31-37, and further including forming a plurality of build-up layers adjacent a top side of the glass core and a bottom side of the glass core; and mounting one or more semiconductor dies mounted on a build-up layer of the plurality of build-up layers.

Example 39 includes the subject matter of any of Examples 31-38, and further including electroplating a plurality of vias on the seed layer in the plurality of cavities.

Example 40 includes the subject matter of any of Examples 31-39, and wherein the plurality of nanowires extend from one or more side walls of the plurality of cavities to a via of the plurality of vias.

Example 41 includes the subject matter of any of Examples 31-40, and wherein the plurality of vias are not in contact with the one or more side walls of the plurality of cavities.

Example 42 includes the subject matter of any of Examples 31-41, and wherein the plurality of nanowires are able to accommodate thermal expansion of the plurality of vias.

Example 43 includes the subject matter of any of Examples 31-42, and wherein individual vias of the plurality of vias are not anchored to side walls of a corresponding cavity of the plurality of cavities.

Example 44 includes the subject matter of any of Examples 31-43, and wherein a gap of at least 10 nanometers is present between at least part of individual vias of the plurality of vias and side walls of a corresponding cavity of the plurality of cavities.

Example 45 includes the subject matter of any of Examples 31-44, and wherein cross-sections of individual vias of the plurality of vias taken perpendicular to the individual vias do not contact side walls of a corresponding cavity of the plurality of cavities.

1. An apparatus comprising:
a substrate core, the substrate core comprising a top side and a bottom side, wherein a plurality of cavities are defined within the substrate core, wherein individual cavities of the plurality of cavities extend from the bottom side to the top side, wherein individual cavities of the plurality of cavities have one or more side walls;
a plurality of vias extending through the plurality of cavities defined in the substrate core; and
a plurality of nanowires extending from the one or more side walls of the plurality of cavities.

2. The apparatus of claim 1, wherein individual nanowires of the plurality of nanowires have a length of 100-5,000 nanometers and a diameter of 50-1,000 nanometers.

3. The apparatus of claim 2, wherein individual nanowires of the plurality of nanowires have a ratio of length to diameter of at least 3.

4. The apparatus of claim 1, wherein individual nanowires of the plurality of nanowires comprise zinc and oxygen.

5. The apparatus of claim 1, wherein the plurality of nanowires extend from the one or more side walls of the plurality of cavities to a via of the plurality of vias.

6. The apparatus of claim 5, wherein the plurality of vias are not in contact with the one or more side walls of the plurality of cavities.

7. The apparatus of claim 1, further comprising a plurality of particles embedded within the plurality of nanowires, wherein individual particles of the plurality of particles comprise palladium.

8. The apparatus of claim 1, wherein individual cavities of the plurality of cavities have an aspect ratio of at least 10.

9. The apparatus of claim 1, further comprising:
a second plurality of nanowires extending from the top side of the substrate core; and
a third plurality of nanowires extending from the bottom side of the substrate core.

10. The apparatus of claim 1, wherein individual vias of the plurality of vias are not anchored to side walls of a corresponding cavity of the plurality of cavities.

11. The apparatus of claim 1, wherein the substrate core is a glass core.

12. The apparatus of claim 1, further comprising:
a plurality of build-up layers adjacent the top side and the bottom side; and
one or more semiconductor dies mounted on a build-up layer of the plurality of build-up layers.

13. An apparatus comprising:
a substrate core, the substrate core comprising a top side and a bottom side, wherein a plurality of cavities are defined within the substrate core, wherein individual cavities of the plurality of cavities extend from the bottom side to the top side, wherein individual cavities of the plurality of cavities have one or more side walls; and
a plurality of nanowires extending from the one or more side walls of the plurality of cavities, wherein individual nanowires of the plurality of nanowires comprise zinc and oxygen.

14. The apparatus of claim 13, further comprising a plurality of vias extending through the plurality of cavities defined in the substrate core.

15. The apparatus of claim 14, wherein the plurality of nanowires are able to accommodate thermal expansion of the plurality of vias.

16. The apparatus of claim 14, wherein individual vias of the plurality of vias are not anchored to side walls of a corresponding cavity of the plurality of cavities.

17. The apparatus of claim 14, wherein a gap of at least 10 nanometers is present between at least part of individual vias of the plurality of vias and side walls of a corresponding cavity of the plurality of cavities.

18. The apparatus of claim 14, wherein cross-sections of individual vias of the plurality of vias taken perpendicular to the individual vias do not contact the one or more side walls of a corresponding cavity of the plurality of cavities.

19. A method comprising:
creating a plurality of cavities in a glass core;
forming a plurality of nanowires in the plurality of cavities; and
electrolessly plating a seed layer in the plurality of cavities.

20. The method of claim 19, further comprising:
attaching a plurality of particles to the plurality of nanowires before electrolessly plating the seed layer, wherein individual particles of the plurality of particles comprise palladium.
